(19) United States
(12) Patent Application Publication
(10) Pub. No.: US 2026/0181920 A1
(43) Pub. Date: Jun. 25, 2026

(54) METHODS, APPARATUSES, AND SYSTEMS FOR THIN FILM RESISTORS

(71) Applicant: STMicroelectronics International N.V., Geneva (CH)

(72) Inventors: Samuele SCIARRILLO, Usmate Velate (IT); Alessia AZZOPARDO, Milano (IT); Paolo COLPANI, Agrate Brianza (IT)

(21) Appl. No.: 18/999,722

(22) Filed: Dec. 23, 2024

(51) Int. Cl. H10D 1/00; H01L 23/528; H01L 23/58; H10D 1/47

(52) U.S. Cl. CPC H10D 1/021; H10D 1/47; H10W 20/43; H10W 42/00

(57) ABSTRACT

Methods, apparatuses, and systems for thin film resistors (TFRs) are provided. An example method includes a semiconductor structure with a device area and resistor area. The resistor area includes thin film resistor patterning. A dielectric layer is formed over the device area and the resistor area. The dielectric layer is etched over the device area. A metal deposition layer is deposited over the device area and the resistor area. The metal layer is etched to expose the TFRs, to form spacers for the TFRs, and to form a metal layer of the device area.

### TECHNOLOGICAL FIELD

Example embodiments of the present disclosure relate generally to thin film resistors, particularly to manufacturing thin film resistors.

### BACKGROUND

Thin film resistors (TFRs) are used in semiconductor devices for their accuracy, stability, reliability, and adaptability, which are vital for high-performance electronic circuits. Applications using TFRs include electronic measuring systems, monitoring equipment, audio applications, precision controls, and instrumentation.

TFRs are produced by applying a thin resistive material layer onto an insulating base or surface. Multiple TFRs may be spaced separately from each other by a distance. However, forming TFRs presents problems when the TFRs are spaced close together at smaller distances. In particular, and with conventional manufacturing techniques, there is a problem of residues that are present during the patterning of metal layer(s) that are on the same or similar layers or surfaces as TFRs. Residue(s) of the metal layer are left in small spaces between the TFRs.

Conventional operations for the patterning of the TFRs and adjacent protective spacers are completed prior to a deposition of a metal layer. After this metal layer is deposited, it must be removed, including from between the TFRs and adjacent protective spacers. Removal of this metal layer is difficult, particularly with small spacing between TFRs. The metal layer will oxidize during lithographic steps, which causes etch stop phenomena that lead to residues after removing the metal layer. The resulting metal residues between adjacent TFRs may reach heights up to several microns. The residues may also be harmful both to the TFRs (leading to short circuits) and to the final passivation layer (leading to damage to its integrity).

The inventors have identified numerous areas of improvement in the existing technologies and processes, which are the subjects of embodiments described herein. Through applied effort, ingenuity, and innovation, many of these deficiencies, challenges, and problems have been solved by developing solutions that are included in embodiments of the present disclosure, some examples of which are described in detail herein.

### BRIEF SUMMARY

Various embodiments described herein relate to methods, apparatuses, and systems for thin film resistors (TFRs), particularly to manufacturing TFRs.

In accordance with some embodiments of the present disclosure, an example manufacturing method of an electronic device is provided. The manufacturing method may comprise: providing a semiconductor substrate comprising a device area and a resistor area; forming a back-end-of-line (BEOL) module overlapping the semiconductor substrate by: forming, at both the device area and the resistor area, a first dielectric layer on the semiconductor substrate; forming, at both the device area and the resistor area, a first metal layer on the first dielectric layer, the first metal layer comprising a plurality of metal portions; forming, at both the device area and the resistor area, a second dielectric layer on the first metal layer; forming, at the resistor area, a first thin film resistor (TFR) element and a second TFR element on the second dielectric layer, the first TFR element and the second TFR element being arranged at a first distance, each of the first TFR element and the second TFR element electrically contacting respective metal portions of the first metal layer, and the first TFR element and the second TFR element comprise a respective resistive layer and an insulating layer in contact with, and on, the respective resistive layer; forming, at the resistor area, a third dielectric layer covering both the first TFR element and the second TFR element and a portion of the second dielectric layer interposed between the first TFR element and the second TFR element; depositing, at both the device area and the resistor area, a metal deposition layer; etching, at both the device area and the resistor area, the metal deposition layer to form, at the device area, a second metal layer on the second dielectric layer electrically contacting respective portions of the first metal layer, and, at the resistor area, a plurality of protective spacers from the third dielectric layer, the a first protective spacer covers a sidewall of the first TFR element and a second protective spacer covers a sidewall of the second TFR element; and a ratio between a thickness of the insulating layer and the first distance is 0.3 or less or a ratio between a thickness of the second metal layer and the insulating layer is greater than or equal 1 and less than or equal to 20.

In some embodiments, etching the metal deposition layer forms a step between the device area and the resistor area.

In some embodiments, the third dielectric layer comprises a first sub-layer and a second sub-layer on the first sub-layer, the first sub-layer comprising a nitride material and the second sub-layer comprising an oxide material.

In some embodiments, the first sub-layer has a thickness greater than, or equal to, 40 nm and less than, or equal to, 60 nm; and the second sub-layer has a thickness greater than, or equal to, 170 nm and less than, or equal to, 230 nm.

In some embodiments, the thickness of the insulating layer of each TFR elements is 400 nm or less.

In some embodiments, the first distance is 1700 nm or less.

In some embodiments, the resistive layer of each TFR elements is a silicon chromium (SiCr) layer and the insulating layer of each TFR elements is a silicon nitride, SiN, layer.

In some embodiments, etching the metal deposition layer forms the second metal layer and the protective spacers in a single etching step.

In some embodiments, the BEOL module comprises a number N of metal layers, an N-th metal layer is the farthermost from the semiconductor substrate, and the second metal layer is the N-th metal layer.

In some embodiments, the first and second metal layers comprises aluminum; and the second metal layer and the resistive layer of each TFR elements electrically contact the respective portions of the first metal layer by respective vias made of a respective conductive material.

In accordance with some embodiments of the present disclosure, an example semiconductor structure is provided. The semiconductor structure may comprise: a semiconductor substrate comprising a device area and a resistor area; a back-end-of-line (BEOL) module overlapping the semiconductor substrate and comprising: at both the device area and the resistor area, a dielectric layer on the semiconductor substrate; at both the device area and the resistor area, a first metal layer comprising a plurality of metal portions, the first metal layer being positioned in a first dielectric layer at a first height; at the resistor area, a first thin film resistor (TFR) element and a second TFR element, the first TFR element and the second TFR element are arranged at a first distance, each of the first TFR element and the second TFR element electrically contacting respective metal portions of the first metal layer, and the first TFR element and the second TFR element comprise a respective resistive layer and an insulating layer in contact with, and on, the respective resistive layer, the first TFR element and the second TFR element are positioned in a second dielectric layer at a second height greater than the first height; at the device area, a second metal layer electrically contacting respective portions of the first metal layer and positioned at the second height; at the resistor area, a plurality of protective spacers including a first protective spacer covering a sidewall of the first TFR element and a second protective spacer covering a sidewall of the second TFR element, the plurality of protective spacers are comprised of a dielectric material; and a ratio between a thickness of the insulating layer of each of the first TFR element and the second TFR element and the first distance is 0.3 or less.

In some embodiments, the semiconductor structure further comprises a step between the device area and the resistor area.

In some embodiments, each protective spacer of the plurality of protective spacers comprises a first sub-layer comprising a nitride material and a second sub-layer comprising an oxide material on the first sub-layer.

In some embodiments, the thickness of the insulating layer of the first TFR element and the second TFR element is 400 nm or less.

In some embodiments, the first distance is 1700 nm or less.

In some embodiments, the BEOL module comprises a number N of metal layers, an N-th metal layer is the farthermost from the semiconductor substrate, and the second metal layer is the N-th metal layer.

In accordance with some embodiments of the present disclosure, a second example the semiconductor structure is provided. This the semiconductor structure may comprise: a semiconductor substrate comprising a device area and a resistor area; a back-end-of-line (BEOL) module overlapping the semiconductor substrate and comprising: at both the device area and the resistor area, a dielectric layer on the semiconductor substrate; at both the device area and the resistor area, a first metal layer comprising a plurality of metal portions, the first metal layer being positioned in a first dielectric layer at a first height; at the resistor area, a first thin film resistor (TFR) element and a second TFR, element, the first TFR element and the second TFR element are arranged at a first distance, each of the first TFR element and the second TFR element electrically contacting respective metal portions of the first metal layer, and the first TFR element and the second TFR element comprise a respective resistive layer and an insulating layer in contact with, and on, the respective resistive layer, the first TFR element and the second TFR element are positioned in a second dielectric layer at a second height greater than the first height; at the device area, a second metal layer electrically contacting respective portions of the first metal layer and positioned at the second height; at the resistor area, a plurality of protective spacers including a first protective spacer covering a sidewall of the first TFR element and a second protective spacer covering a sidewall of the second TFR element, the plurality of protective spacers are comprised of a dielectric material; and a ratio between a thickness of the second metal layer and the insulating layer is greater than or equal 1 and less than or equal to 20.

In some embodiments, the thickness of the insulating layer of each TFR elements is 400 nm or less.

In some embodiments, the BEOL module comprises a number N of metal layers, an N-th metal layer is the farthermost from the semiconductor substrate, and the second metal layer is the N-th metal layer.

In some embodiments, the thickness of the second metal layer is greater than, or equal to, 2,500 nm and less than, or equal to, 3,500 nm.

The above summary is provided merely for purposes of summarizing some example embodiments to provide a basic understanding of some aspects of the disclosure. Accordingly, it will be appreciated that the above-described embodiments are merely examples and should not be construed to narrow the scope or spirit of the disclosure in any way. It will also be appreciated that the scope of the disclosure encompasses many potential embodiments in addition to those here summarized, some of which will be further described below.

### BRIEF DESCRIPTION OF THE DRAWINGS

Having thus described certain example embodiments of the present disclosure in general terms, reference will now be made to the accompanying drawings, which are not necessarily drawn to scale, and wherein:

FIGS. 1A and 1B illustrate exemplary cross-section views of a semiconductor structure in accordance with one or more embodiments of the present disclosure;

FIGS. 2A-2K illustrate exemplary cross-section views of various operations in forming a semiconductor structure in accordance with one or more embodiments of the present disclosure; and

FIG. 3 illustrates a flowchart of example operations for forming a semiconductor structure in accordance with one or more embodiments of the present disclosure.

### DETAILED DESCRIPTION

Some embodiments of the present disclosure will now be described more fully herein with reference to the accompanying drawings, in which some, but not all, embodiments of the disclosure are shown. Indeed, various embodiments of the disclosure may be embodied in many different forms and should not be construed as limited to the embodiments set forth herein; rather, these embodiments are provided so that this disclosure will satisfy applicable legal requirements. Like reference numerals refer to like elements throughout.

As used herein, the term “comprising” means including but not limited to and should be interpreted in the manner it is typically used in the patent context. Use of broader terms such as comprises, includes, and having should be understood to provide support for narrower terms such as consisting of, consisting essentially of, and comprised substantially of.

The phrases “in various embodiments,” “in one embodiment,” “according to one embodiment,” “in some embodiments,” and the like generally mean that the particular feature, structure, or characteristic following the phrase may be included in at least one embodiment of the present disclosure and may be included in more than one embodiment of the present disclosure (importantly, such phrases do not necessarily refer to the same embodiment).

The word “example” or “exemplary” is used herein to mean “serving as an example, instance, or illustration.” Any implementation described herein as “exemplary” is not necessarily to be construed as preferred or advantageous over other implementations.

If the specification states a component or feature “may,” “can,” “could,” “should,” “would,” “preferably,” “possibly,” “typically,” “optionally,” “for example,” “often,” or “might” (or other such language) be included or have a characteristic, that a specific component or feature is not required to be included or to have the characteristic. Such a component or feature may be optionally included in some embodiments or it may be excluded.

### Overview

Various embodiments described herein relate to methods, apparatuses, and systems for thin film resistors (TFRs), particularly to manufacturing TFRs. TFR patterning may allow for placing TFRs, including for connecting two or more TFRs in parallel and/or series, such as through using vias to a different metal layers. Forming TFRs as described herein may provide for elimination or reduction of residue(s) between TFRs during back end of line processes or operations.

The elimination or reduction of residue increases effectiveness of TFRs by allowing TFR patterning to be closer distances. This may allow for more TFRs to be placed closer together. It may allow for creating the longest resistive path in a smallest possible area and/or reduce the footprint of one or more components on a die. Regardless of the patterning, adjacent TFRs have to be laterally insulated with dielectrics protective spacers or protective spacers to avoid short-circuits among the adjacent TFRs. Embodiments of the present disclosure provide for TFRs to be located closer together by minimizing and/or eliminating metal residues in manufacturing of semiconductor structures.

The present disclosure allows for reduction of an aspect ratio of the TFR patterning and, thus, reducing the risk of residues. The aspect ratio is a ratio of a height of the TFR patterning of a first TFR and a distance to an adjacent TFR. Reducing the aspect ratio by reducing the height allows for TFRs at closer distances. In various embodiments of the present disclosure, one or more operational steps may be omitted from conventional techniques. For example, the present disclosure does not require a dedicated patterning step or operation for protective spacers before depositing and patterning a metal layer.

In various embodiments, the TFR patterning is a pattern of a resistive layer (a.k.a., thin film layer) covered by an insulating layer (a.k.a, hard mask layer). Decreasing the aspect ratio may be provided by decreasing the height of the TER patterning, including the insulating layer, without increasing the spacing between adjacent TFRs. In various embodiments, this is possible by omitting a conventional operational step of patterning protective spacers before depositing and patterning a metal level.

In embodiments of the present disclosure, the dielectrics above TFR patterning are eroded or removed only during an etching of a metal layer. This leads to a decrease in the aspect ratio and decrease in residues. This reduction is due to a lower risk of top barrier cracking during metal etching.

During manufacturing of integrated circuits with TFRs, a semiconductor material wafer may have a first side, front side, or front end with active components (e.g., capacitor, transistors, diodes, etc.) and then connect these components or active elements with a stack configuration of oxide and metal layers and the like. The stack configuration is arranged above the front side with the active components interposed between the stack configuration and the substrate. The stack configuration commonly is named back-end-of-line (BEOL) of the device. In various embodiments, the back end of line may be provided with, for example, TFRs in a BEOL module. Additionally, various embodiments may also include capacitors on the same side and/or surface as the TFRs in a BEOL module. Operations performed on this back end of the stack for forming a BEOL module are referred to as back end of line (BEOL) processes or operations. Formations of TFRs in accordance with one or more embodiments of the present disclosure are BEOL processes or operations.

### Exemplary Systems, Apparatuses, and Methods

Embodiments of the present disclosure herein include methods, apparatuses, and systems for TFRs, particularly to manufacturing TFRs.

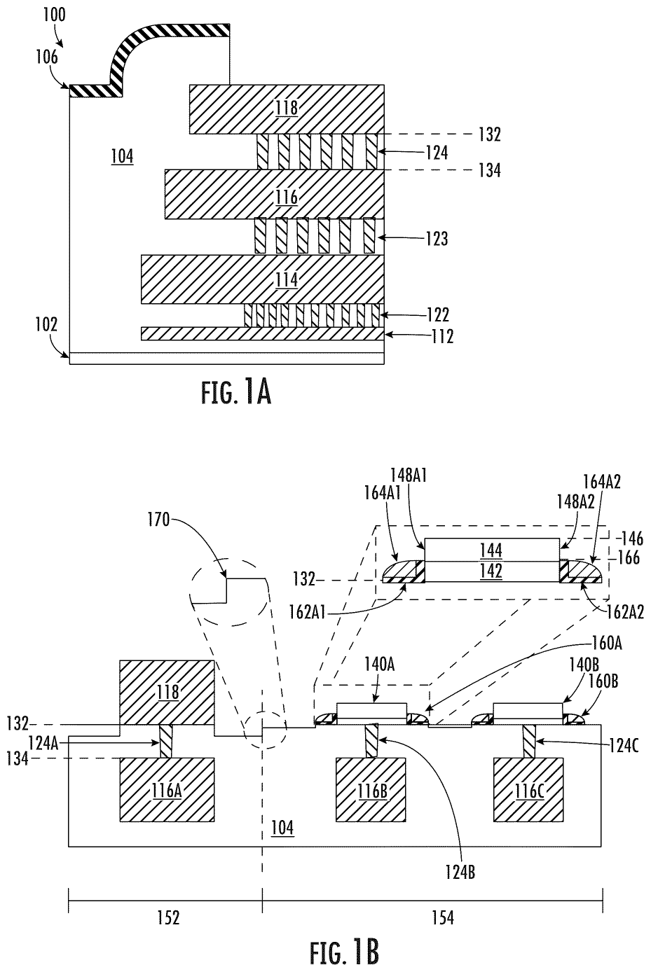

FIGS. 1A and 1B illustrate exemplary cross-section views of a semiconductor structure in accordance with one or more embodiments of the present disclosure. The semiconductor structure may be part of an electronic device with a BEOL module.

FIG. 1A illustrates an exemplary cross-section view of a semiconductor structure in accordance with one or more embodiments of the present disclosure. The semiconductor structure 100 may include a substrate 102, a dielectric layer 104 (over the substrate 102), a passivation layer 106, a pre-metal layer 112 connected by one or more vias 122 to a metal layer 114, the metal layer 114 connected to a metal layer 116 by one or more vias 123, and metal layer 116 connected by one or more vias 124 to a metal layer 118. In various embodiments, the dielectric layer 104 may be formed from multiple dielectric layers, such as a first dielectric layer 104A and a second dielectric layer 104 as described herein, which may each be made of the same material and formed during separate operations. In various embodiments, the metal layer 114 may be referred to as a first metal layer 114, the metal layer 116 may be referred to as a second metal layer 116, and the metal layer 118 may be referred to as a third metal layer 118 or final metal layer (e.g., the final metal layer of a BEOL process). The number of metal layers is purely exemplary, with the semiconductor substrate that may comprise any number of metal layers (e.g., more than 1 and less than 15). The semiconductor structure 100 illustrated may be back end of line (BEOL) portion of a semiconductor device.

The bottom of the metal layer 118 may located at a first level 132. The top of the metal layer 116 may be located at second level 134.

In various embodiments, the metal layers 112, 114, 116, and 118 may comprise aluminum, such as, for example, aluminum copper (AlCu). The vias 122, 123, 124 may be made of a conductive material, such as, for example, tungsten (W). Thus, and as illustrated, the one or more metal layers may be electrically contacting each other with the one or more vias 122, 123, 124.

FIG. 1B illustrates an exemplary cross-section view of a semiconductor structure in accordance with one or more embodiments of the present disclosure. The cross-section view may be of a portion of a BEOL module. The BEOL module includes a number N of metal layers (e.g., 116, 118), wherein the N-th metal layer is the farthermost from the semiconductor substrate. In various embodiments, metal layer 118 is this N-th metal layer. This exemplary cross-section view of FIG. 1B illustrates a dielectric layer 104 that has a device area 152 and a resistor area 154. The dielectric layer 104 may be referred to as an intermetal dielectric (IMD) layer. The device area 152 may be where one or more device layers may be located. The resistor area 154 may be where the TFR elements 140 are located. The TFR elements 140 collectively may be referred to as a TFR patterning. While FIG. 1B illustrates a cross-section view with two TFR elements 140 (e.g., 140A, 140B), it will be appreciated that additional TFR elements 140 beyond the two illustrated are included in embodiments of the present disclosure. It will also be appreciated that some active components could be present on the substrate 102, including at the resistor area. However, the TFR elements 140 are only located in the BEOL module at the resistor area and not at the device area.

In various embodiments the TFR elements 140 and the metal layer 118 are both located on the first level 132. The TFR elements 140 electrically contact one or more portions of the metal layer 116. In particular, vias 124 may electrically connect one or more portions of the metal layer 116 to one or more portions of the metal layer 118 and one or more portions of the TFR elements 140. For example, a first via 124A may electrically connect a top portion of the metal layer 116A at second level 134 to the bottom of the metal layer 118 at a first level 132. A second via 124B may electrically connect a top portion of the metal layer 116B at second level 134 to the bottom of a first TFR element 140A (in particular, a respective resistive layer 142 of TFR element 140A) at a first level 132. A third via 124C may electrically connect a top portion of the metal layer 116C at second level 134 to the bottom of a second TFR element 140B (in particular, a respective resistive layer 142 of TFR element 140B) at a first level 132.

In various embodiments, a TFR element 140 may be surrounded by one or more protective spacers 160 (e.g., 160A, 160B). The one or more protective spacers 160 may be located on or around the sidewall 148 (e.g., 148A1, 148A2) of a TFR element 140 (e.g., 140A). A TFR element 140 may be made of resistive layer 142 (a.k.a. thin film layer) that is covered with an insulating layer 144 (a.k.a. hard mask layer). In various embodiments, the resistive layer 142 may be made of silicon chromium (SiCr) that forms a SiCr layer. In various embodiments, the insulating layer 144 may be made of silicon nitride (SiN). A protective spacer 160 (e.g., 160A, 160B) may include a SiN spacer layer 162 (e.g., 162A, 162B) covered by an oxide spacer layer 164 (e.g., 164A, 164B). A protective spacer 160 may protect some or all of the TFR element 140 from oxidation and prevent exposure to one or more external processes or operations. It will be appreciated that FIG. 1B is a cross-section view and that a protective spacer 160 may surround a TFR element 140. Thus, while a protective spacer 160A is illustrated as being on the left (e.g., 162A1, 164A1) and right (e.g., 162A2, 164A2) of TFR element 140A, protective spacer 160A may surround the TFR element 140A.

In conventional semiconductor devices, a protective spacer may be formed before deposition of a metal layer at the same level, e.g., first level 132, as a TFR. For example, a protective spacer may be formed before defining a third metal layer. Conventional protective spacers include a protective spacer extending to have one or more portions that are at a TFR surface level 146 to the top of the height of the sidewall 148 (e.g., 148A1, 148A2) of the TFR element 140. In various embodiments of the present disclosure, the protective spacers (e.g., 160A) extend or rise to a protective spacer level (e.g., 166) that is below the height of the sidewall 148 of the TFR element 140, and not the same as, the TFR surface level 146. Alternatively, in various embodiments of the present disclosure (not shown in the figures), the protective spacers (e.g., 160A) extend or rise (substantially) to TFR level 146, covering the whole sidewall 148 of each TFR element 140. For example, the heights of the protective spacers 160 and of the TFR elements 140 are both within a range centered in a nominal thickness value and having-10% (preferably-5%) of the nominal thickness value as a minimum, and +10% (preferably +5%) of the nominal thickness value as a maximum.

In various embodiments of the present disclosure, there may be a step 170 between the device area 152 and the resistor area 154. The step 170 may be referred to as a step profile. This step may be developed from one or more etch operations described herein. The step 170 may have the device area surface level being lower than the resistor area surface level at the first level 132. In various embodiments, the TFR elements 140 are on the same level (or above) the metal layer 118, and vias 124 are electrically connected to the TFR elements 140 and the metal layer 118 from below.

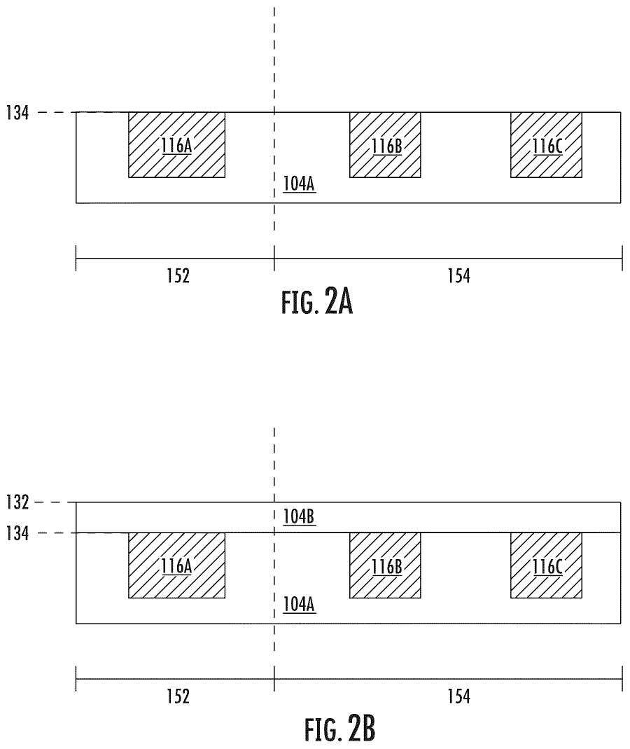

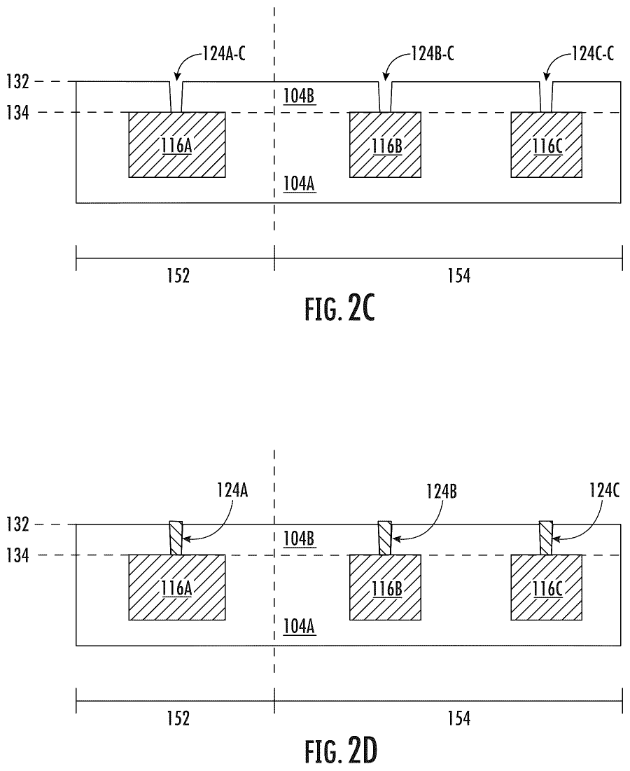

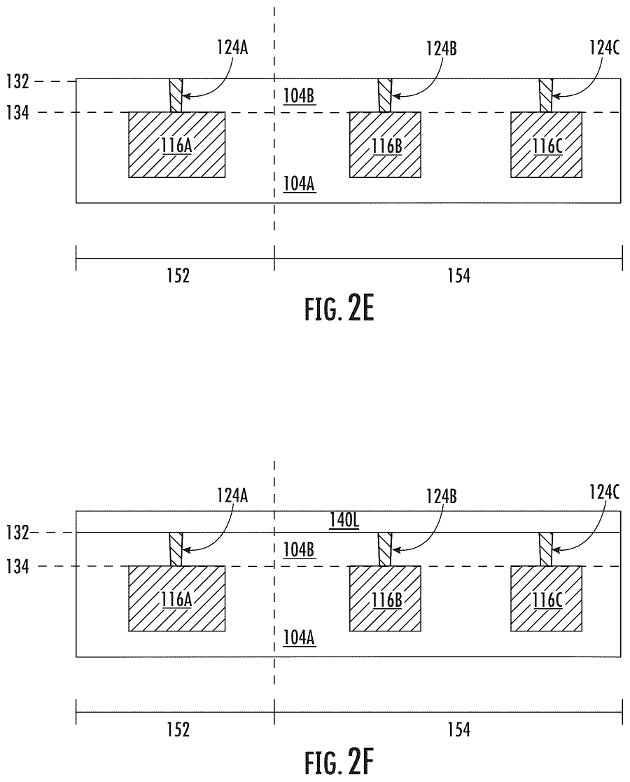

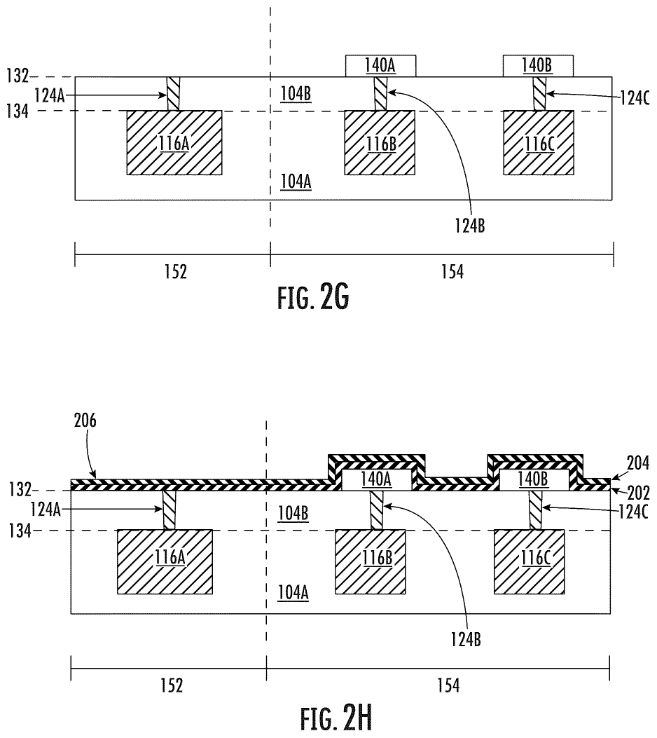

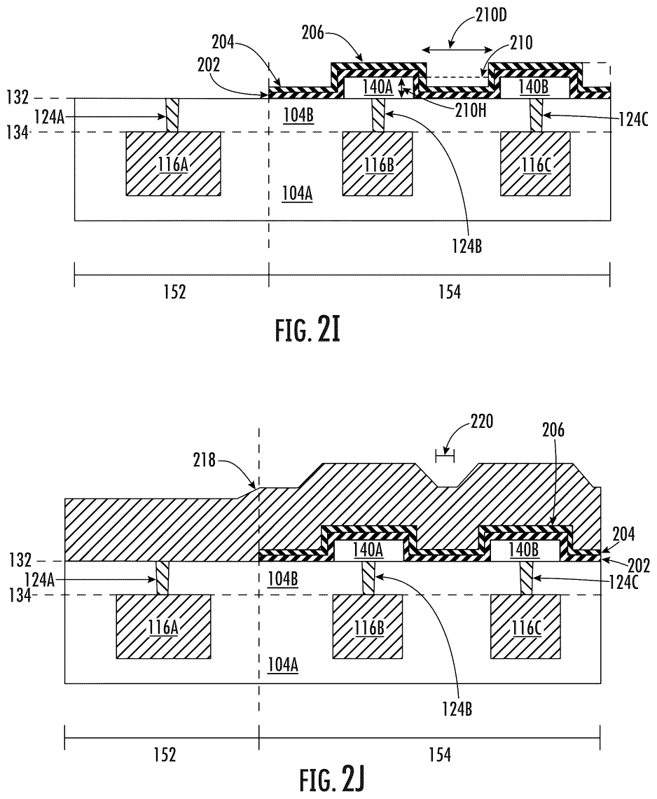

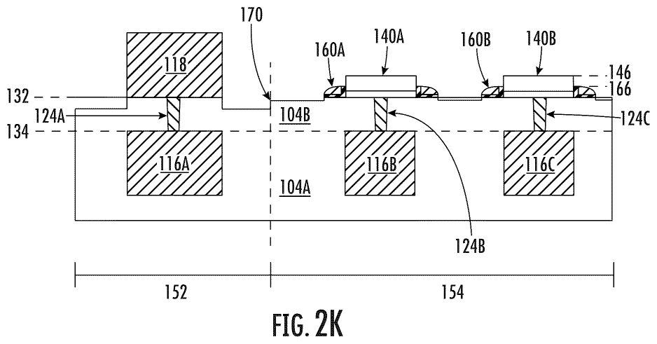

FIGS. 2A-2K illustrate exemplary cross-section views of various operations in forming a semiconductor structure in accordance with one or more embodiments of the present disclosure. The semiconductor structure may be a part of an electronic device with a back-end-of-line (BEOL) module.

FIG. 2A illustrates a first exemplary cross-section view of an operation in forming a semiconductor structure in accordance with one or more embodiments of the present disclosure. A semiconductor structure is provided with a first dielectric layer 104A with one or more portions of a metal layer 116 (e.g., 116A, 116B, 116C) exposed at the second level 134.

FIG. 2B illustrates a first exemplary cross-section view of an operation in forming a semiconductor structure in accordance with one or more embodiments of the present disclosure. A second dielectric layer 104B is formed over the second level 134 to a height of the first level 132. The second dielectric layer 104B, when formed over the second level 134, covers the device area 152 and the resistor area 154 so that the first dielectric layer 104A and the one or more portions one or more portions of a metal layer 116 (e.g., 116A, 116B, 116C) are covered. In various embodiments, the second dielectric layer 104B is made of the same material as the first dielectric layer 104A and, once formed, the first dielectric layer 104A and the second dielectric layer 104B may be treated in some embodiments as one dielectric layer 104.

FIG. 2C illustrates a first exemplary cross-section view of an operation in forming a semiconductor structure in accordance with one or more embodiments of the present disclosure. Via cavities 124-C (e.g., 124A-C, 124B-C, 124C-C) for vias 124 (e.g., 124A, 124B, 124c) are formed in the top of the second dielectric layer 104B. The via cavities 124-C are formed at least from the first level 132 to the one or more portions of a metal layer 116 at the second level 134. The via cavities may be formed by patterning.

FIG. 2D illustrates a first exemplary cross-section view of an operation in forming a semiconductor structure in accordance with one or more embodiments of the present disclosure. Vias 124 (e.g., 124A, 124B, 124C) are formed by filling the via cavities 124-C with a via material. In various embodiments, the via material may be tungsten. In various embodiments, the filling of the via cavities 124-C may leave one or more portions of the via material(s) of the vias 124 above the first level 132.

FIG. 2E illustrates a first exemplary cross-section view of an operation in forming a semiconductor structure in accordance with one or more embodiments of the present disclosure. After filling the via cavities 124-C with via material, the top of the structure may be polished (e.g., chemical mechanical polishing operation) at first level 132. This polishing may lower the level of the via material at the mouth or top of via cavities 124-C and avoid overfilling of the vias 124 above the first level 132.

FIG. 2F illustrates a first exemplary cross-section view of an operation in forming a semiconductor structure in accordance with one or more embodiments of the present disclosure. After polishing, a TFR layer 140L is deposited over the structure at the first level 132. In various embodiments, the TFR layer 140L is used to create the TFR elements 140. The deposition of the TFR layer 140L may include deposition of a resistive layer 142 and an insulating layer 144. These may then be collectively patterned to form the TFR elements 140.

FIG. 2G illustrates a first exemplary cross-section view of an operation in forming a semiconductor structure in accordance with one or more embodiments of the present disclosure. A TFR patterning with hard mask is provided. The thin film resistor patterning of the TFR layer 140L is provided on a semiconductor structure with a first level 132 that includes a metal layer 116 with a second level 134 electrically connected with a plurality of vias 124 (e.g., 124A, 124B, 124C) to the first level 132.

The thin film resistor patterning may include a first TFR element 140A and a second TFR element 140B. Each TFR element (e.g., 140A) may be comprised of a resistive layer 142 and an insulating layer 144. The thin film resistor patterning may be electrically connected to one or more portions of a metal layer 116 by one or more vias 124. The TFR patterning occurred after the patterning and formation of the vias 124. A first TFR element 140A of the thin film resistor patterning may be electrically connected with a via 124B to a portion of the metal layer 116B. A second TFR element 140B of the thin film resistor patterning may be electrically connected with a via 124C to a portion of the metal layer 116C. In various embodiments, FIG. 2G is associated with operation 310.

FIG. 2H illustrates a first exemplary cross-section view of an operation in forming a semiconductor structure in accordance with one or more embodiments of the present disclosure. A third dielectric layer 206 is deposited over the first surface 132 and TFR patterning. In various embodiments, the third dielectric layer 206 is comprised of a first sub-layer of dielectric material 202 that is covered by a second sub-layer of dielectric material 204. In various embodiments, the first sub-layer 202 may be made of a nitride material, such as SiN, which may form a SiN layer. In various embodiments, the second sub-layer 204 may be made of an oxide material, which may form an oxide layer. In various embodiments, the first sub-layer 202 of a SiN layer and the second sub-layer of an oxide layer may collectively be referred to as a SiN/oxide layer. In various embodiments, the first sub-layer 202 is deposited first and then the second sub-layer 204 is deposited over the first sub-layer 202. In various embodiments, the first sub-layer 162 has a thickness greater than or equal to 30 nm and less than or equal to 70 nm, for example equal to about 50 nm, and the second dielectric sub-layer 164 has a thickness greater than or equal to 100 nm and less than or equal to 300 nm, for example equal to about 200 nm. In various embodiments, FIG. 2H is associated with operation 312.

FIG. 2I illustrates a first exemplary cross-section view of an operation in forming a semiconductor structure in accordance with one or more embodiments of the present disclosure. The third dielectric layer 206 is etched for the device 152 and outside of the resistor area 154. In various embodiments, FIG. 2I is associated with operation 314.

The etching of the third dielectric layer 206 may be performed by masking the resistor area with TFR patterning with a mask. One or more portions or all of the device area 152 may not be etched. An etch may be performed to remove the third dielectric layer 206 from the device area 152 to expose the first surface 132 and the via(s) (e.g., 124A) of the device area 152.

A spacing aspect area 210 is illustrated in FIG. 2I. The spacing aspect area 210 has an aspect ratio, defined by the ratio of the height 210H of the spacing aspect area 210 divided by the distance 210D of the spacing aspect area 210. The height 210H of the spacing aspect area 210 is (at least) the height (or thickness) of insulating layer 144 of the TFR element 140. The height of the resistive layer 142 may be neglected with respect to the height of the insulating layer 144. Furthermore, it is also possible to neglect the height of the third dielectric layer (present on both the top surface and the sidewalls of the TFR element 140) because the deposition of the third dielectric layer 206 is uniform and conformal (i.e., high adherence of the third dielectric layer 206 to the below structure, following the profile of the below structure) over the resistor area. The distance 210D of the spacing aspect area 210 may be (at least) the distance between two TFRs elements 140A and 140B (preferably neglecting the thickness of the third dielectric layer 206). In various embodiments, the aspect ratio is 0.3 or less, preferably is 0.2 or less. In various embodiments, the height of the spacing aspect area 210 (preferably of the insulating layer 144) is 400 nm or less, preferably is 300 nm or less. In various embodiments, the distance 210D of the spacing aspect area 210 (preferably between two TFR elements 140A and 140B) is 1,700 nm or less, preferably is 1,500 nm or less. In various embodiments, an aspect ratio of 0.3 or less may be associated with a resistive layer 142 of 50 nm and an insulating layer 144 of 200 nm. In various embodiments, the insulating layer 144 may be 300 nm or less.

In various embodiments the height of the spacing aspect area 210 may be (or is) chosen based on the height (or thickness) of the metal layer 118. In various embodiments, with the metal layer 118 having a thickness in a first range from 2,500 nm to 3,500 nm (preferably from 2,800 nm to 3,200 nm, for example 3000 nm), the height (or thickness) of the insulating layer 144 is greater than or equal to 150 nm (preferably 200 nm) and less than or equal to 600 nm (preferably 500 nm, more preferably 400 nm), for example equal to 300 nm. In various embodiments, with the metal layer 118 having a thickness in a second range from 800 nm to 1,500 nm (preferably from 900 nm to 1200 nm, for example 1,000 nm), the height (or thickness) of the insulating layer 144 is greater than or equal to 50 nm (preferably 80 nm) and less than or equal to 350 nm (preferably 300 nm), for example equal to 200 nm. In various embodiments, a ratio between the thickness of the metal layer 118 and of the insulating layer 144 is greater than or equal to 1 and less than or 20, preferably greater than or equal to 3 and less than or 15, more preferably greater than or equal to 8 and less than or 12, for example equal to 10. The thickness of the insulating layer 144 may be (proportionally) modulated with the desired (or required) thickness of the metal layer 118. This allows to optimize the overall design of the semiconductor device. By selecting the proper thickness of the insulating layer 144 following the above selection rules, it is possible to minimize the spacing among the TFRs without, at the same time, generating any metal residues at the end of the etching process illustrated with reference to FIG. 2K.

FIG. 2J illustrates a first exemplary cross-section view of an operation in forming a semiconductor structure in accordance with one or more embodiments of the present disclosure. A metal deposition layer 218 may be deposited over both the device area 152 and the resistor area 154. As the metal deposition layer 218 is associated with the metal layer 118 as described herein, it may be referred to as the metal deposition layer. The deposition of the metal deposition layer 218 over the resistor area 154 includes the metal deposition layer 218 being layered over the third dielectric layer 206. In various embodiments, FIG. 2J is associated with operation 316.

The metal deposition layer 218, when deposited, may include one or more spaced portions 220 that are associated with the space between the TFR elements 140. The one or more spaced portions 220 may include a flat portion for the length of the spaced portion 220. In various embodiments, the flat portion may allow for a subsequent etch operation to be performed that have minimized or no residue.

The spaced portion 220 may also be a flat portion that is possible given the low aspect ratio of the protective spacer definition operations described herein. In contrast to conventional methods, the protective spacers 160 described in the present disclosure are not created in a dedicated etching step before depositing the metal deposition layer 218 but, instead, are formed in the same etching step that etches the metal deposition layer 218. By avoiding a dedicated etching step as in conventional methods, the present disclosure makes it possible to use a relatively thin insulating layer 144 (having for example a thickness below 350 nm, preferably below 320 nm, e.g., equal to about 300 nm) over the resistive layer 142 (e.g., a SiCr layer), thus reducing the overall height of the stack spacer (i.e., the distance from the first surface 132 to the top of the third dielectric layer 206 above a TFR elements 140). In various embodiments, the overall height of the stack spacer may have an overall height or thickness of about 250 nm. At a given distance (e.g., 1500 nm) between a first TFR element 140A and a second TFR element 140B, it is possible to have a smaller aspect ratio.

FIG. 2K illustrates a first exemplary cross-section view of an operation in forming a semiconductor structure in accordance with one or more embodiments of the present disclosure. The metal deposition layer 218 is etched to form the metal layer 118 and the protective spacers 160A, 160B The metal layer 118 is electrically connected from below to the metal layer 116A by via 124A. The TFR element 140A is electrically connected from below to the metal layer 116B by via 124B. The TFR element 140B is electrically connected from below to metal layer 116C by via 124C. In various embodiments, FIG. 2K is associated with operation 318.

The metal layer 118 is formed by the etching of metal deposition layer 218. The etch operation removes the metal deposition layer 218 in the resistor area 154 and the third dielectric layer 206 above the TFR elements 140A, 140B. The protective spacers 160A, 160B are formed during the etch operation. The etch operation removes the metal deposition layer 218 in the resistor area 154 and includes forming the protective spacers 160A, 160B associated with the TFR elements 140A, 140B. During the etching of metal deposition layer 218, it is also possible to remove the third dielectric layer 206. However, at portions close to the TFR elements, the etching slurry is not able to completely remove the third dielectric layer. Consequently, residues of third dielectric layer 206 remains in proximity of the TFR elements, thus forming the protective spacers 160. In various embodiments, the protective spacers 160 are formed with the protective spacer level 166 below the TFR surface level 146. Therefore, as explained above, within the single etching step 308 is possible to create both the metal layer 118 and the protective spacer 160 acting as protective structures for the sidewalls of the TFR element 140. The present invention therefore does not contemplate a dedicated step for the formation of the protective spacers 160 before the formation of the metal layer 118.

In various embodiments, the etch may create a step 170 between the device area 152 and resistor area 154.

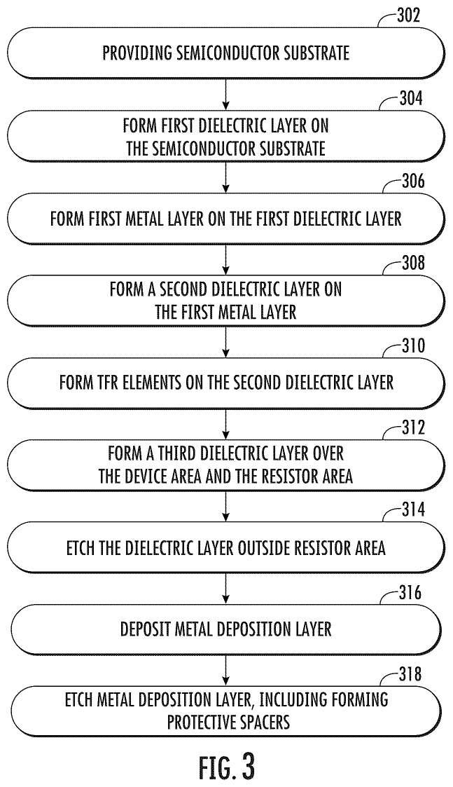

FIG. 3 illustrates a flowchart of example operations for forming a semiconductor structure in accordance with one or more embodiments of the present disclosure. The semiconductor structure may be, or may be part of, an electronic device with a back-end-of-line (BEOL) module.

At operation 302, a semiconductor substrate is provided. The semiconductor substrate includes a device area 152 and a resistor area 154. The semiconductor substrate may be used for forming a BEOL module of the semiconductor device.

At operation 304, a first dielectric layer is formed on the semiconductor substrate. A BEOL module may be formed on the semiconductor substrate. The BEOL module may include first forming a first dielectric layer 104A on the semiconductor substrate. In various embodiments, the BEOL module may already have had one or more additional dielectric layers and/or metal layers formed in the BEOL module.

At operation 306, a first metal layer is formed on the first dielectric layer. A first metal layer may be formed on the first dielectric layer 104A. The first metal layer 116 may include a plurality of metal portions (e.g., 116A, 116B, 116C). After being formed, the first dielectric layer 104A and the first metal layer 116 with the plurality of metal portions may share top surface at the second level 134. FIG. 2A illustrates various embodiments after the performance of operation 306.

At operation 308, a second dielectric layer is formed on the first metal layer. A second dielectric layer 104B may be formed on the surface of the first dielectric layer 104A and the plurality of metal portions of the first metal layer 116. FIG. 2B illustrates various embodiments after the performance of operation 308.

At operation 310, TFR elements are formed on the second dielectric layer. TFR elements 140 (e.g., 140A, 140B) are formed on the second dielectric layer 104B. In various embodiments, the second dielectric layer 104B may have a plurality of via cavities 124-C formed. The via cavities 124-C may be filled with a via material to form a plurality of vias 124. The forming of the plurality of vias 124 may be by filling the via cavities 124-C with a via material (e.g., tungsten). The filling of the via cavities 124-C may have the via material overflow the top of the second dielectric layer 104B at a first level 132. One or more chemical mechanical polishing operations may be used to remove the overflow material of the vias 124. A TFR layer 140L may be deposited on the first level 132. A plurality of TFR elements 140 (e.g., a first TFR element 140A and a second TFR element 140B) may be formed from the TFR layer 140L by patterning the TFR layer 140L. FIG. 2G illustrates various embodiments after the performance of operation 310.

At operation 312, a third dielectric layer is deposited over the device area and the resistor area. The third dielectric layer 206 is deposited over the first surface 132 and TFR elements 140, including over the device area 152 and the resistor area 154. The third dielectric layer 206 includes a first sub-layer 202 (e.g., SiN layer) that is covered by a second sub-layer 204 (e.g., oxide layer). In various embodiments, the first sub-layer 202 is deposited first and then the second sub-layer 204 is deposited over the first sub-layer 202. In various embodiments, FIG. 2H illustrates various embodiments after the performance of operation 312.

At operation 314, the third dielectric layer is etched outside the resistor area. The third dielectric layer 206 is etched for the device 152 and outside of the resistor area 154. Thus the third dielectric layer is formed to cover the resistor area 154 but not the device area 152. This include the third dielectric layer 206 covering both the first TFR element 140, the second TFR element 140B, and a portion of the second dielectric layer interposed between the first TFR element 140A and the second TFR element 140B. In various embodiments, FIG. 2I illustrates after the performance of operation 314.

At operation 316, a metal deposition layer is deposited. The metal deposition layer 218 may be associated with the metal layer 118. The metal deposition layer 218 may be deposited over both the device area 152 and the resistor area 154. In various embodiments, FIG. 2J illustrates after the performance of operation 316.

At operation 318, the metal deposition layer is etched, including forming protective spacers. The metal deposition layer 218 is etched to form the second metal layer 118 and the protective spacers 160A, 160B. The second metal layer 118 is formed on the second dielectric layer 104B and is electrically contacting respective portions of the first metal layer 116 (i.e., 116A). At the resistor area, a plurality of protective spacers 160 are formed from the third dielectric layer 206, including a first protective spacer 160A for the first TFR element 140A and a second protective spacer 160B for the second TFR element 140B. The first protective spacer 160A covers a sidewall 148A of the first TFR element 140A. The second protective spacer 160B covers a sidewall 148B of the second TFR element 140B. The first protective spacer 140A and the second protective spacer 140B may have a height (e.g., at 166) smaller than a height of the first TFR element 140A and a height of the second TFR element 140B (e.g., at 146). Alternatively, the protective spacers 160 extend substantially at the same height as the TFR elements 140. In various embodiments, FIG. 2K illustrates after the performance of operation 318. By forming the protective spacers during this metal layer etching, a decrease in the aspect ratio and/or a reduction or elimination in the formation of residue is provided.

In various embodiments, the metal layer etching of operation 318 forms a step 170 between the device area 152 and the resistor area 154. The step may be a step profile that surrounds the resistor area 154.

It should be readily appreciated that the embodiments of the systems and apparatuses, described herein may be configured in various additional and alternative manners in addition to those expressly described herein.

### CONCLUSION

Operations and/or functions of the present disclosure have been described herein, such as in flowcharts. As will be appreciated, computer program instructions may be loaded onto a computer or other programmable apparatus (e.g., hardware) to produce a machine, such that the resulting computer or other programmable apparatus implements the operations and/or functions described in the flowchart blocks herein. These computer program instructions may also be stored in a computer-readable memory that may direct a computer, processor, or other programmable apparatus to operate and/or function in a particular manner, such that the instructions stored in the computer-readable memory produce an article of manufacture, the execution of which implements the operations and/or functions described in the flowchart blocks. The computer program instructions may also be loaded onto a computer, processor, or other programmable apparatus to cause a series of operations to be performed on the computer, processor, or other programmable apparatus to produce a computer-implemented process such that the instructions executed on the computer, processor, or other programmable apparatus provide operations for implementing the functions and/or operations specified in the flowchart blocks. The flowchart blocks support combinations of means for performing the specified operations and/or functions and combinations of operations and/or functions for performing the specified operations and/or functions. It will be understood that one or more blocks of the flowcharts, and combinations of blocks in the flowcharts, can be implemented by special purpose hardware-based computer systems which perform the specified operations and/or functions, or combinations of special purpose hardware with computer instructions.

While this specification contains many specific embodiments and implementation details, these should not be construed as limitations on the scope of any disclosures or of what may be claimed, but rather as descriptions of features specific to particular embodiments of particular disclosures. Certain features that are described herein in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

While operations and/or functions are illustrated in the drawings in a particular order, this should not be understood as requiring that such operations and/or functions be performed in the particular order shown or in sequential order, or that all illustrated operations be performed, to achieve desirable results. In certain circumstances, operations and/or functions in alternative ordering may be advantageous. In some cases, the actions recited in the claims may be performed in a different order and still achieve desirable results. Thus, while particular embodiments of the subject matter have been described, other embodiments are within the scope of the following claims.

While this detailed description has set forth some embodiments of the present invention, the appended claims cover other embodiments of the present invention which differ from the described embodiments according to various modifications and improvements.

Within the appended claims, unless the specific term “means for” or “step for” is used within a given claim, it is not intended that the claim be interpreted under 35 U.S.C. § 112, paragraph 6.

1. A manufacturing method of an electronic device, the manufacturing method comprising:
providing a semiconductor substrate comprising a device area and a resistor area;
forming a back-end-of-line (BEOL) module overlapping the semiconductor substrate by:
forming, at both the device area and the resistor area, a first dielectric layer on the semiconductor substrate;
forming, at both the device area and the resistor area, a first metal layer on the first dielectric layer, the first metal layer comprising a plurality of metal portions;
forming, at both the device area and the resistor area, a second dielectric layer on the first metal layer;
forming, at the resistor area, a first thin film resistor (TFR) element and a second TFR element on the second dielectric layer, the first TFR element and the second TFR element being arranged at a first distance, each of the first TFR element and the second TFR element electrically contacting respective metal portions of the first metal layer, and wherein the first TFR element and the second TFR element comprise a respective resistive layer and an insulating layer in contact with, and on, the respective resistive layer;
forming, at the resistor area, a third dielectric layer covering both the first TFR element and the second TFR element and a portion of the second dielectric layer interposed between the first TFR element and the second TFR element;
depositing, at both the device area and the resistor area, a metal deposition layer;
etching, at both the device area and the resistor area, the metal deposition layer to form, at the device area, a second metal layer on the second dielectric layer electrically contacting respective portions of the first metal layer, and, at the resistor area, a plurality of protective spacers from the third dielectric layer, wherein the a first protective spacer covers a sidewall of the first TFR element and a second protective spacer covers a sidewall of the second TFR element; and
wherein a ratio between a thickness of the insulating layer and the first distance is 0.3 or less; or
wherein a ratio between a thickness of the second metal layer and the insulating layer is greater than or equal 1 and less than or equal to 20.

2. The manufacturing method of claim 1, wherein etching the metal deposition layer forms a step between the device area and the resistor area.

3. The manufacturing method of claim 1, wherein the third dielectric layer comprises a first sub-layer and a second sub-layer on the first sub-layer, the first sub-layer comprising a nitride material and the second sub-layer comprising an oxide material.

4. The manufacturing method of claim 3, wherein the first sub-layer has a thickness greater than, or equal to, 40 nm and less than, or equal to, 60 nm; and
wherein the second sub-layer has a thickness greater than, or equal to, 170 nm and less than, or equal to, 230 nm.

5. The manufacturing method of claim 1, wherein the thickness of the insulating layer of each TFR elements is 400 nm or less.

6. The manufacturing method of claim 1, wherein the first distance is 1700 nm or less.

7. The manufacturing method of claim 1, wherein the resistive layer of each TFR elements is a silicon chromium (SiCr) layer and the insulating layer of each TFR elements is a silicon nitride, SiN, layer.

8. The manufacturing method of claim 1, wherein etching the metal deposition layer forms the second metal layer and the protective spacers in a single etching step.

9. The manufacturing method of claim 1, wherein the BEOL module comprises a number N of metal layers, wherein an N-th metal layer is the farthermost from the semiconductor substrate, and the second metal layer is the N-th metal layer.

10. The manufacturing method of claim 1, wherein the first and second metal layers comprises aluminum; and
wherein the second metal layer and the resistive layer of each TFR elements electrically contact the respective portions of the first metal layer by respective vias made of a respective conductive material.

11. A semiconductor structure comprising:
a semiconductor substrate comprising a device area and a resistor area;
a back-end-of-line (BEOL) module overlapping the semiconductor substrate and comprising:
at both the device area and the resistor area, a dielectric layer on the semiconductor substrate;
at both the device area and the resistor area, a first metal layer comprising a plurality of metal portions, the first metal layer being positioned in a first dielectric layer at a first height;
at the resistor area, a first thin film resistor (TFR) element and a second TFR element, wherein the first TFR element and the second TFR element are arranged at a first distance, each of the first TFR element and the second TFR element electrically contacting respective metal portions of the first metal layer, and wherein the first TFR element and the second TFR element comprise a respective resistive layer and an insulating layer in contact with, and on, the respective resistive layer, wherein the first TFR element and the second TFR element are positioned in a second dielectric layer at a second height greater than the first height;
at the device area, a second metal layer electrically contacting respective portions of the first metal layer and positioned at the second height;
at the resistor area, a plurality of protective spacers including a first protective spacer covering a sidewall of the first TFR element and a second protective spacer covering a sidewall of the second TFR element, wherein the plurality of protective spacers are comprised of a dielectric material; and
wherein a ratio between a thickness of the insulating layer of each of the first TFR element and the second TFR element and the first distance is 0.3 or less.

12. The semiconductor structure of claim 11 further comprising a step between the device area and the resistor area.

13. The semiconductor structure of claim 11, wherein each protective spacer of the plurality of protective spacers comprises a first sub-layer comprising a nitride material and a second sub-layer comprising an oxide material on the first sub-layer.

14. The semiconductor structure of claim 11, wherein the thickness of the insulating layer of the first TFR element and the second TFR element is 400 nm or less.

15. The semiconductor structure of claim 11, wherein the first distance is 1700 nm or less.

16. The semiconductor structure of claim 11, wherein the BEOL module comprises a number N of metal layers, wherein an N-th metal layer is the farthermost from the semiconductor substrate, and the second metal layer is the N-th metal layer.

17. A semiconductor structure comprising:
a semiconductor substrate comprising a device area and a resistor area;
a back-end-of-line (BEOL) module overlapping the semiconductor substrate and comprising:
at both the device area and the resistor area, a dielectric layer on the semiconductor substrate;
at both the device area and the resistor area, a first metal layer comprising a plurality of metal portions, the first metal layer being positioned in a first dielectric layer at a first height;
at the resistor area, a first thin film resistor (TFR) element and a second TFR, element, wherein the first TFR element and the second TFR element are arranged at a first distance, each of the first TFR element and the second TFR element electrically contacting respective metal portions of the first metal layer, and wherein the first TFR element and the second TFR element comprise a respective resistive layer and an insulating layer in contact with, and on, the respective resistive layer, wherein the first TFR element and the second TFR element are positioned in a second dielectric layer at a second height greater than the first height;
at the device area, a second metal layer electrically contacting respective portions of the first metal layer and positioned at the second height;
at the resistor area, a plurality of protective spacers including a first protective spacer covering a sidewall of the first TFR element and a second protective spacer covering a sidewall of the second TFR element, wherein the plurality of protective spacers are comprised of a dielectric material; and
wherein a ratio between a thickness of the second metal layer and the insulating layer is greater than or equal 1 and less than or equal to 20.

18. The semiconductor structure of claim 17, wherein the thickness of the insulating layer of each TFR elements is 400 nm or less.

19. The semiconductor structure of claim 17, wherein the BEOL module comprises a number N of metal layers, wherein an N-th metal layer is the farthermost from the semiconductor substrate, and the second metal layer is the N-th metal layer.

20. The semiconductor structure of claim 17, wherein the thickness of the second metal layer is greater than, or equal to, 2,500 nm and less than, or equal to, 3,500 nm.
